(19) United States
(12) Patent Application Publication
(10) Pub. No.: US 2012/0150378 A1
(43) Pub. Date: Jun. 14, 2012

(54) Determination and Usage of Reserve Energy in Stored Energy Systems

(75) Inventors: Chetan Kumar Maini, Bangalore (IN); Prakash Ramaraju, Bangalore (IN); Chandramouli Ramasarma, Banglaore (IN); Nagendra Babu Sathyanarayana, Bangalore (IN)

(73) Assignee: REVA ELECTRIC CAR COMPANY (PVT) LIMITED, Bangalore (IN)

(21) Appl. No.: 13/391,569

(22) PCT Filed: Aug. 18, 2010
(86) PCT No.: PCT/IN2010/000548

§ 371 Date: Feb. 21, 2012

(30) Foreign Application Priority Data
Aug. 21, 2009 (IN) 1992/CHE/2009
Aug. 18, 2010 (IN) PCT/IN2010/000548

(51) Int. Cl. G06F 7/00; G06F 19/00; G01R 21/00

(52) U.S. Cl. 701/22; 702/60; 701/1

(57) ABSTRACT

A method and system for determining amount of internal reserve energy that is available in an energy storage system is provided. The method includes determining capacity of the energy storage system to store energy and computing the amount of internal reserve energy available below a threshold level based on the determined capacity. Further, state of health of the energy storage system is determined based on historical data that is collected. Additionally, current state of the energy storage system is determined. The state of health of the energy storage system and current state of the energy storage system is used to refine the amount of internal reserve energy.

### TECHNICAL FIELD

Embodiments relate to Energy Storage Systems in general, and more particularly, embodiments relate to internal reserve energy that is available in an Energy Storage System.

### BACKGROUND

Energy Storage Systems (ESS) are used for storing energy that can be consumed by one or more energy consumption systems. An example of an ESS is a pack of lead acid batteries. The ESS being capable of storing and supplying energy, finds a wide variety of applications, such as, powering an Uninterrupted Power Supply system and at least partially propelling vehicles, among other applications. Generally, the extent to which the energy stored in an ESS can be consumed is restricted to a certain level to ensure that life and performance of the ESS is optimized.

As the energy stored in an ESS is consumed, the energy available for consumption gradually reduces and reaches a reserve level. Generally, users of the ESS are advised to let consumption of the energy stored in the ESS till the reserve level. However, consumption of the energy from the ESS is generally allowed beyond the reserve level till the energy stored in the ESS reaches a threshold level. At the threshold level, state of charge of the ESS reaches to zero percent. Even at this level, even though the state of charge of the ESS has reached to zero percent charge, a certain amount of internal reserve energy still exists in the ESS. The internal reserve energy is generally not allowed to be used. Hence, in situations where ESS at least partially propels a vehicle, the user of the vehicle will be left stranded if the state of charge of the ESS reaches zero percentage. The user will not even be able to drive the vehicle to park the same in a safe location, or drive the vehicle to a near by location where the ESS can be recharged. Further, the amount of internal reserve energy that exists when the energy stored in the ESS reaches the threshold level will not be known. Additionally, the work that can be done if the internal reserve energy is consumed will also not be known.

### STATEMENT OF THE INVENTION

An embodiment provides a method for determining amount of internal reserve energy that is available in an Energy Storage System. The method includes determining capacity of the Energy Storage System to store energy and computing the amount of internal reserve energy available below a threshold level based on the determined capacity. Further, state of health of the Energy Storage System is determined based on historical data that is collected. Additionally, current state of the Energy Storage System is determined. The state of health of the Energy Storage System and current state of the Energy Storage System is used to refine the amount of internal reserve energy.

An embodiment provides a system for determining amount of internal reserve energy that is available in an Energy Storage System. The system is coupled to the Energy Storage System. The system includes an Energy Management System which includes at least one input and output device, at least one memory device, at least one processor, and at least one transmitting and receiving device. The input and output device is configured to at least collect data from the Energy Storage System and send commands to the Energy Storage System. Further, the memory device is configured to store at least a part of the data collected by the input and output device. The processor is configured to process at least a part of the data collected from the Energy Storage System, and the transmitting and receiving device is configured to send at least a part of the processed data and receive data. The system further comprises a Data Processing System which is configured to receive data sent by the transmitting and receiving device and determine state of health of the Energy Storage System and current state of the energy storage system, wherein the Data Processing System is configured to compute the amount of internal reserve energy available based on the state of health of the Energy Storage System.

Another embodiment provides a system for determining amount of internal reserve energy that is available in an Energy Storage System. The system is coupled to the Energy Storage System. The system includes at least one Energy Management System which includes at least one input and output device, at least one memory device and at least one processor. The input and output device(s) is configured to at least collect data from the Energy Storage System and send commands to the Energy Storage System. The memory device is configured to store at least a part of the data collected by the input and output device and the processor is configured to process at least a part of the data collected from the Energy Storage System and determine state of health of the Energy Storage System and current state of the Energy Storage System, wherein the processor is configured to compute the amount of internal reserve energy available based on the state of health of the Energy Storage System and current state of the Energy Storage System.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF FIGURES

Embodiments are illustrated in the accompanying drawings, throughout which like reference letters indicate corresponding parts in the various figures. The embodiments herein will be better understood from the following description with reference to the drawings, in which:

FIG. 1 is a block diagram illustrating an Energy Storage System, an Energy Consumption System and an Energy Management System, in accordance with an embodiment herein;

FIG. 2a illustrates Energy Storage System as a container for the purpose of understanding, in accordance with an embodiment herein;

FIG. 2b is a graph illustrating energy consumption from an ESS, in accordance with an embodiment herein;

FIG. 3a illustrates a system for determining amount of internal reserve energy that is available in ESS, in accordance with an embodiment herein;

FIG. 3a illustrates a system for determining amount of internal reserve energy that is available in an ESS, in accordance with an embodiment herein;

FIG. 4 is a flow chart illustrating a method for determining amount of internal reserve energy that is available in an ESS, in accordance with an embodiment herein;

FIG. 5 is a graph illustrating the amount of internal reserve energy available in an ESS, in accordance with an embodiment herein;

FIG. 6 is a graph illustrating amount of internal reserve energy available in an ESS as a function of change in temperature of the ESS while charging, in accordance with an embodiment herein;

FIG. 7 is a graph illustrating the energy stored in an ESS, in accordance with an embodiment herein;

FIG. 8 is a graph illustrating the energy stored in an ESS, in accordance with an embodiment herein;

FIG. 8b is a graph illustrating variation of impedance in an ESS, in accordance with an embodiment herein;

FIG. 9 is a graph illustrating the energy available in an ESS, in accordance with an embodiment herein; and

FIG. 10 is a flow chart illustrating a method of determining amount of work that can be done using internal reserve energy, in accordance with an embodiment herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

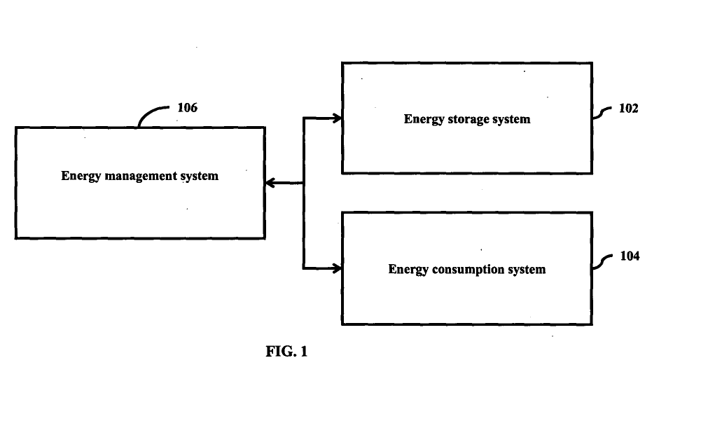

The embodiments herein provide a method and system for determining amount of internal reserve energy that is available in an energy storage system. Referring now to the drawings, and more particularly to FIGS. 1 through 10, where similar reference characters denote corresponding features consistently throughout the figures, there are shown preferred embodiments.

FIG. 1 is a block diagram illustrating an Energy Storage System (ESS) 102, an Energy Consumption System (ECS) 104 and an Energy Management System (EMS) 106, in accordance with an embodiment. The ESS 102 stores energy which can at least partially be consumed by at least one ECS 104.

The ESS 102 may include one or more of Lead-acid battery, Gel battery, Lithium ion battery, Lithium ion polymer battery, NaS battery, Nickel-iron battery, Nickel metal hydride battery, Nickel-cadmium battery, and capacitors among others, or combination thereof. The ECS 104 which consumes the energy stored in the ESS 102 may be one or more of drive train, motor controller, cabin climate control, subsystem climate control, charging system, dashboard display, car access system, drive motor, seat climate control, cabin HVAC, add-on heating system, battery heater, battery ventilation, on board charger, safety system, crash sensor, sensing system, temperature sensor, fluid level sensor, and pressure sensor, among others, or combination thereof. The extent to which the energy stored in the ESS 102 can be consumed is controlled by the EMS 106.

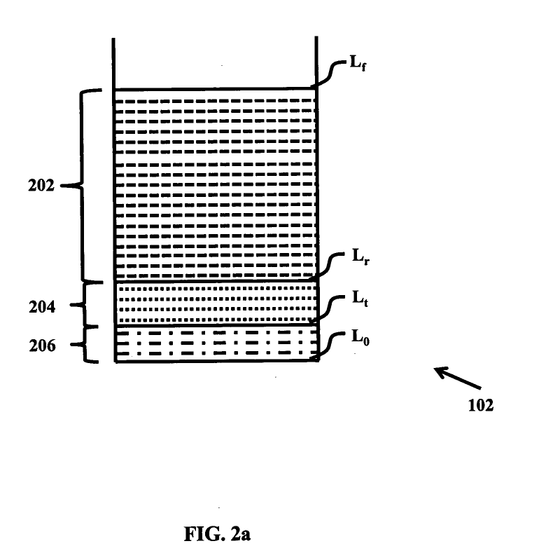

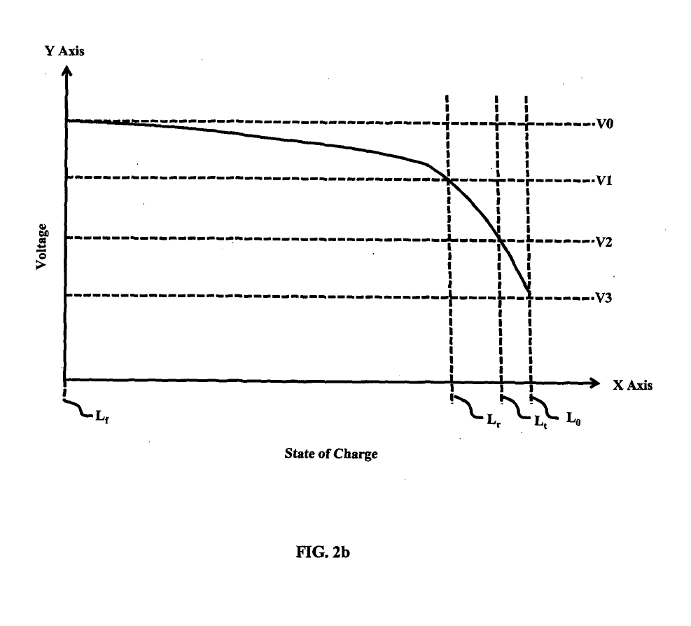

The EMS 106 is programmed to allow consumption of energy from the ESS 102 until at least one threshold level is reached. However, even beyond the threshold level, energy will be available in the ESS 102. The energy that is available beyond the threshold level is known as internal reserve energy. FIG. 2a illustrates ESS 102 as a container for the purpose of understanding, in accordance with an embodiment. The ESS 102 is divided into three zones, namely, zone A 202, zone B 204, and zone C 206. In FIG. 2a, zone A 202 lies between lines L_{f} and Lᵣ, zone B 204 lies between the lines Lᵣ and Lₜ, and zone C 206 lies between the lines Lₜ and Lₒ. The energy in zone A 202 is allowed to be consumed from the ESS 102 under normal conditions. Further, the energy in zone B 204 is the reserve energy, and zone C 206 is a zone in which internal reserve energy which is generally not available for consumption exists. The line L_{f} represents a level till which the—energy is stored in the ESS 102 when the ESS 102 is completely ‘filled’, which means,—energy is stored in the ESS 102 till the level L_{f} when level of energy of the ESS 102 is 100%. As the energy is consumed from the ESS 102, the ‘energy stored’ in the ESS 102 reduces. The ‘energy storage level’ of the ESS 102 reduces to a level Lᵣ which is referred to as reserve level. The energy is allowed to be consumed even beyond this level till the energy stored in the ESS 102 drops to a threshold level represented by the line Lₜ. At a stage when energy stored in the ESS 102 drops to the threshold level, the state of charge of the ESS 102 will be 0%. The energy that is available below the threshold level is referred to as the internal reserve energy. An example showing the energy that is stored in the ESS 102 may also be illustrated by means of a graph. FIG. 2b is a graph illustrating energy consumption from the ESS 102, in accordance with an embodiment. In the graph, the energy stored in the ESS 102 is being consumed by ECS 104 which is exerting constant load, thereby reducing the energy stored in the ESS 102. In the graph, Y axis represents the voltage of the ESS 102 and the X axis represents the state of charge of the ESS 102. When the state of charge of the ESS 102 is 100%, the voltage of the ESS 102 is V0. Further, as the energy is consumed, the voltage gradually reduces to V1, at a stage when the energy stored in the ESS 102 reaches reserve level. Subsequently, as the energy is further consumed, the voltage of the ESS 102 further reduces from V1 to V2 at a stage when the energy stored in the ESS 102 reaches the threshold level. Further, if the energy is used beyond the threshold level, the internal reserve energy is utilized during which the voltage of the ESS 102 reduces from V2 to V3. It may be noted that the reserve level indicated by Lᵣ may be accordingly configured between the level L_{f} and threshold level Lₜ. Further, the threshold level Lₜ can be configured between Lᵣ and L₀. In an embodiment, the configuration of the threshold level is based on the configuration of the ESS 102. The configuration of the threshold level may be different for different types of ESS, such as Lead-acid battery, Gel battery, Lithium ion battery, Lithium ion polymer battery, NaS battery, Nickel-iron battery, Nickel metal hydride battery, Nickel-cadmium battery, and capacitors. Further, the threshold level may vary based on the capacity of the ESS 102 to store energy. Further, the internal reserve energy that is available below the threshold level varies based on one or more factors

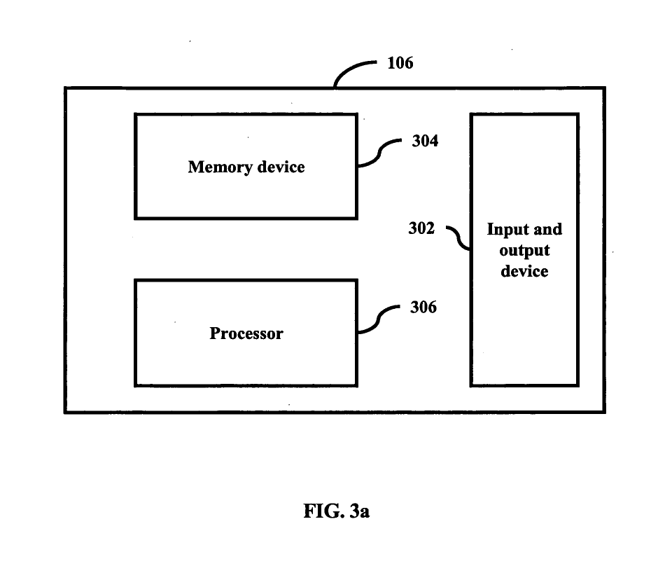

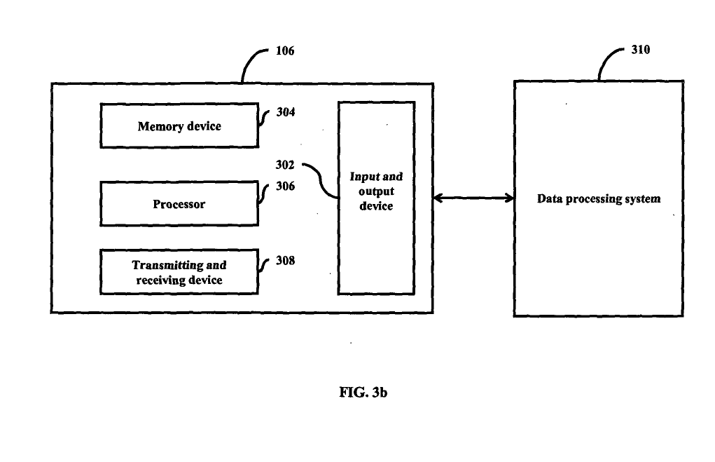

FIG. 3 illustrates a system for determining amount of internal reserve energy that is available in ESS 102, in accordance with an embodiment. The system includes the EMS 106. The EMS 106 includes at least one processor 306, at least one memory device 304 and at least one input and output (I/O) device 302. The Processor 306 is capable of receiving and processing data obtained from the I/O device 302 and memory device 304. Further, the processor 306 is capable of sending data to the memory device 304 for storage. Additionally, the processor 306 is capable of sending commands to I/O device 302 which in turn are communicated to devices associated with the I/O device 302. In an embodiment, processor 306 is made of electronic circuits comprising commercially available general purpose microcontroller chips. The memory device 304 may comprise a combination of volatile and non volatile memory chips that can store information in digital form. In an embodiment, the I/O device 302 comprises sets of input and output lines each of which is individually connected to the processor 306. These input and output lines may be a combination of analog inputs, analog outputs, digital inputs, digital outputs, pulse/frequency outputs and data lines. In some embodiments, the EMS 106 may further comprise at least one transmitting and receiving device 308, and at least one Data Processing System (DPS) 310, as illustrated in FIG. 3b. The EMS 106 and the DPS 310 are connected wirelessly over a telecommunication network. The processor 306 is further configured to communicate with the DPS 310 by sending and receiving data through the transmitting and receiving device 308. The transmitting and receiving device 308 communicates with the DPS 310 through the telecommunication network. The processor 306 is further configured to process data received from the DPS 310. In an embodiment, the system enables determination of amount of internal reserve energy that is available in the ESS 102.

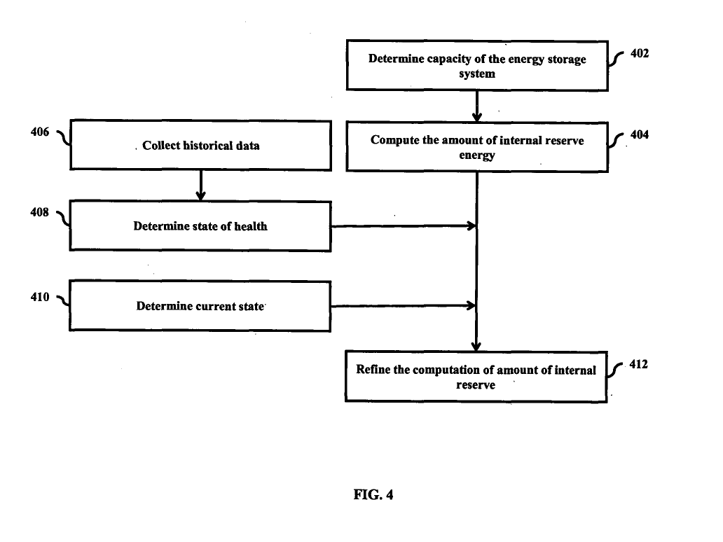

FIG. 4 is a flow chart illustrating a method for determining amount of internal reserve energy that is available in the ESS 102. At step 402 capacity of the ESS 102 to store energy is determined. Subsequently, based on the determined capacity, the amount of internal reserve energy available below the threshold level is determined at step 404. Further, historical data relating to the ESS 102 is collected at step 406. At least a part of the collected historical data is used to determine State of Health (SOH) of the ESS 102 at step 408. Additionally, current state of the ESS 102 is determined at step 410. The current state of the ESS 102 and the SHO of the ESS 102 are used to refine the amount of internal reserve energy computed at step 404.

In an embodiment, I/O device 302 collects data from the ESS 102 and stores data in the memory device 304. The processor 306 retrieves at least a part of the data stored in the memory device 304 and determines the capacity of the ESS 102 to store energy. The processor 306 utilizes the determination of capacity of the ESS 102 to compute the amount of internal reserve energy stored in the ESS 102 below the threshold level. The processor 306 further retrieves at least a part of data collected and stored in the memory device 304 over a period of time, referred to as historical data to determine SOH of the ESS 102. The processor 306 additionally uses at least a part of data collected relating to the ESS 102 to determine current state of the ESS 102. The current state and SOH of the ESS 102 are used by the processor 306 to refine the computation of amount of internal reserve energy stored in the ESS 102.

In an embodiment, the amount of internal reserve energy stored in the ESS 102 is computed by EMS 106 and DPS 310 which are coordinating with each other to compute the amount of internal reserve energy stored in the ESS 102. To determine the amount of internal reserve energy, I/O device 302 collects data from the ESS 102 and stores data in the memory device 304. The processor 306 retrieves at least a part of the data stored in the memory device 304 and determines the capacity of the ESS 102 to store energy. Alternatively, the data required to compute the capacity is sent to the DPS 310 by transmitting and receiving device 306. The DPS 310 determines the capacity of the ESS 102. The determined capacity of the ESS 102 is used either by the processor 306 or the DPS 310 to compute the amount of internal reserve energy stored in the ESS 102 below the threshold level. Further, the historical data that is used to determine the SOH of the ESS 102 is stored in the memory device 304 or in the DPS 310. Alternatively, part of the historical data is stored in the memory device 304 and the remaining part is stored in the DPS 310. Further, based on the configuration of the EMS 106 and the DPS 310, the SOH of the ESS 102 is determined by the processor 306 or DPS 310 using required historical data. Further, the EMS 106 or DPS 310 determines the current state of the ESS. The current state and SOH of the ESS 102 are used by the processor 306 to refine the computation of amount of internal reserve energy stored in the ESS 102. The SOH may be provided to the processor 306 by the DPS 310. Alternatively, the current state and SOH of the ESS 102 are used by the DPS 310 to refine the computation of amount of internal reserve energy stored in the ESS 102. The SOH and current state may be provided to the DPS 310 by the EMS 106.

The various actions in the above method may be performed in the order presented, in a different order or simultaneously. Further, in some embodiments, some actions listed may be omitted if they are not needed to generate the needed result.

The computation of amount of internal reserve energy that exists at a point of time as hereinabove mentioned is refined based on SOH of the ESS 102 and current state of the ESS 102.

The amount of internal reserve energy available in the ESS 102 that is computed based on the capacity of the ESS 102 is refined by decreasing the computed amount of internal reserve energy as the SOH of the ESS 102 deteriorates. In an embodiment involving electrical energy, refinement of amount of internal reserve is based on factors affecting the SOH which include one or more of, capacity of the ESS 102 to store energy, cycles of usage of the ESS 102, recharging behaviour of the ESS 102, number of charge and discharge cycles the ESS 102 has experienced, temperature of the ESS102, and impedance of the ESS 102, among others.

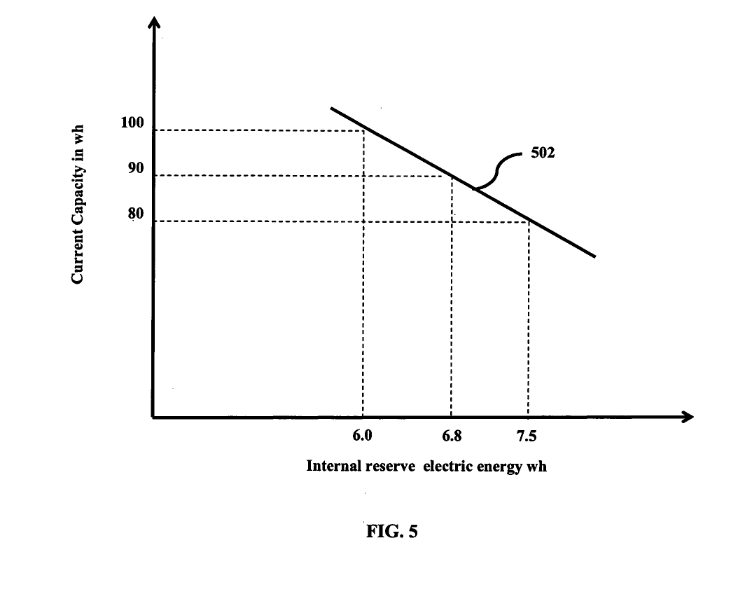

The capacity of the ESS 102 to store energy declines as the health of the ESS 102 deteriorates. Hence, the SOH of the ESS 102 is indirectly proportional to the capacity of the ESS 102 to storeenergy. Therefore, the maximum amount of energy that is stored in the ESS 102 when the ESS is ‘full’ (100% SOC in an embodiment where ESS 102 is a battery) is an indication of SOH of the ESS 102. Further, as the SOH of the ESS 102 deteriorates, the amount of internal reserve energy available in the ESS 102 also declines. FIG. 5 is a graph illustrating the amount of internal reserve energy available in the ESS 102, in accordance with an embodiment. In the graph, the ESS 102 comprises Lithium Iron Phosphate Batteries which are at approximately 25 degree Celsius. The line 502 indicates the amount of internal reserve energy available in the ESS 102. The amount of internal reserve energy gradually declines as the capacity of the ESS 102 to store energy declines. The computation of amount of internal reserve energy is refined by reducing the computed amount of reserve energy with reduction in the capacity of the energy storage system to store energy.

Further, the cycles of usage of the ESS is used to refine the computation of amount of internal reserve energy stored in the ESS 102. The computed amount of internal reserve energy is refined by reducing the computed amount of internal reserve energy with increase in the cycles of usage of the energy storage system.

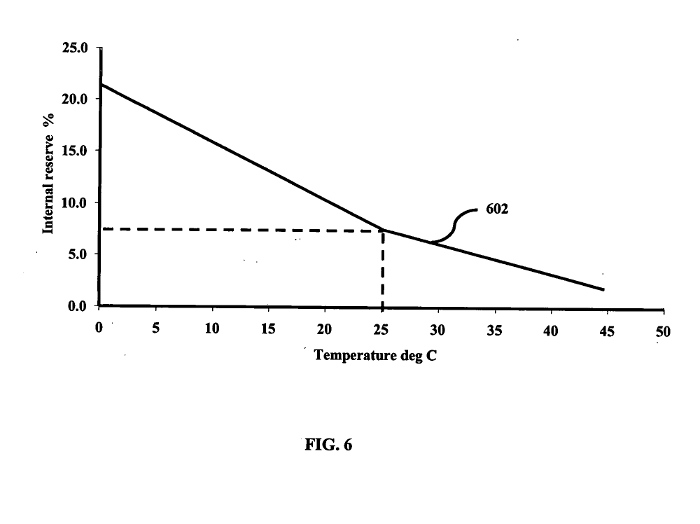

In an embodiment, recharging behaviour of the ESS 102 is considered for refining the computation of amount of internal reserve energy in the ESS 102. In an embodiment, an increase in the time taken to completely charge the ESS 102 is an indication of deterioration of SOH of the ESS 102. Further, increase in the temperature of ESS 102 to undesirable levels while charging the ESS 102 is an indication of deterioration of SOH of the ESS 102. FIG. 6 is a graph illustrating amount of internal reserve energy available in ESS 102 as a function of change in temperature of the ESS 102 while charging, in accordance with an embodiment. In the graph, the line 602 indicates the amount of internal reserve energy in an ESS 102 comprising Lithium Iron Phosphate Batteries. The internal reserve energy available in ESS 102 varies as the temperature of the ESS 102 varies. The amount of internal reserve energy in an ESS 102 is refined by increasing or decreasing the calculated amount of internal reserve energy in accordance with the temperature of the ESS 102.

In an embodiment, behaviours while recharging the ESS 102 other than the ones mentioned above may be considered for determining the SOH of the ESS 102.

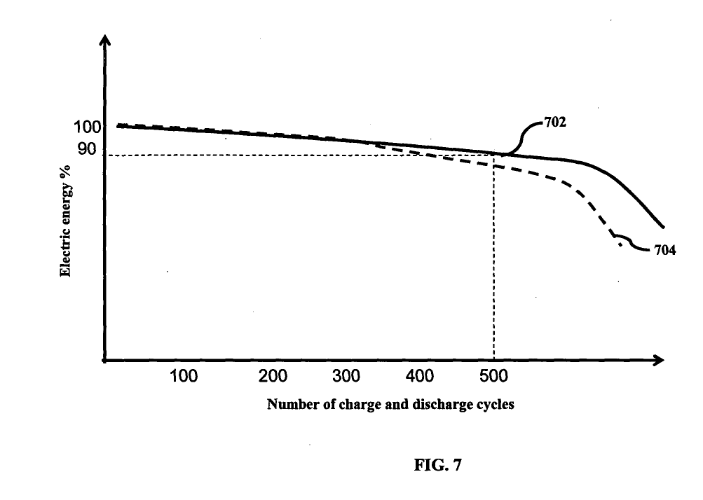

In an embodiment, number of charge and discharge cycles the ESS 102 has experienced is considered for refining the computation of amount of internal reserve energy. It has been observed that the SOH of the ESS 102 deteriorates as the number of charge and discharge cycles experienced by the ESS 102 increases. Hence, the SOH of the ESS 102 is a function of number of charge and discharge cycles the ESS 102 has experienced. As the SOH of ESS 102 deteriorates, the capacity of the ESS 102 to store energy also declines. Further, as the capacity to store the energy declines, the availability of internal reserve energy also declines. FIG. 7 is a graph illustrating the energy stored in the ESS 102, in accordance with an embodiment. In the graph the line 702 indicates the energy that is expected to be stored in the ESS 102 based on the type of ESS 102. Further, line 704 indicates the actual capability of ESS 102 to store energy, in accordance with an embodiment. The energy that can be stored declines, as the number of charge and discharge cycles experienced by the ESS 102 increases. The computation of the amount of internal reserve energy stored in the ESS 102 is refined by reducing the computed amount of internal reserve energy with increase in the number of charge and discharge cycles the ESS 102 has experienced.

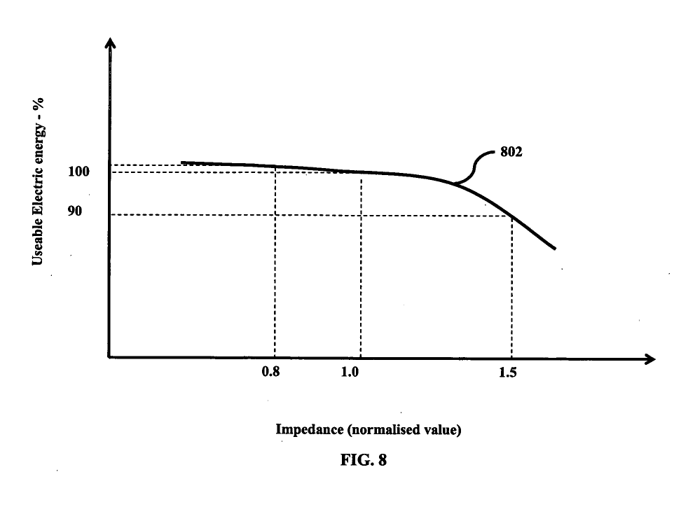

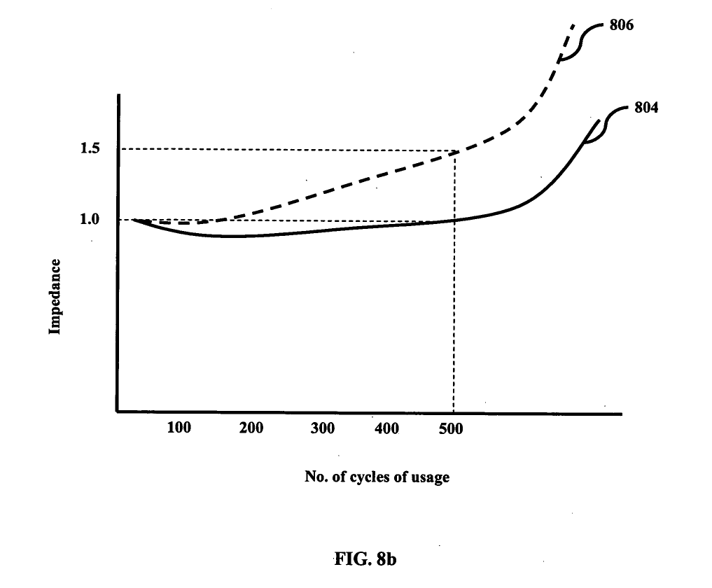

In an embodiment, the impedance of the ESS 102 is considered to determine the SOH of the ESS 102. It has been observed that the SOH of the ESS 102 deteriorates as the impedance of the ESS 102 increases. FIG. 8 is a graph illustrating the energy stored in the ESS 102, in accordance with an embodiment. In the graph, the line 802 indicates the energy that can be stored in the ESS 102. The energy that can be stored declines, as the impedance of the ESS 102 increases. The computation of amount of internal reserve energy stored in the ESS 102 is refined by reducing the computed amount of internal reserve energy with increase in the impedance of the ESS 102. Further, as indicated in FIG. 8b, in accordance with an embodiment, the impedance of ESS 102 may not vary as expected. In the graph, line 804 indicates the expected variation of impedance of ESS 102, and line 806 indicates the actual variation of impedance of ESS 102 as the number of charge/discharge cycle of ESS 102 increases. This difference between the intended and actual variation of impedance can also be used to refine the computation of amount of internal reserve energy stored in the ESS 102.

In an embodiment, the SOH is derived from of one or more of, capacity of the ESS 102 to store energy, age of the ESS 102, recharging behaviour of the ESS 102, number of charge and discharge cycles the ESS 102 has experienced, the temperature rise behaviour of the ESS 102, and impedance of the ESS 102, among others, which are collected over a period of time. In an embodiment, the period of time begins when the ESS 102 is first used. Data representing one or more of, capacity of the ESS 102 to store energy, age of the ESS 102, recharging behaviour of the ESS 102, number of charge and discharge cycles the ESS 102 has experienced, and impedance of the ESS 102, among others, which are collected over a period of time may be referred to as historical data.

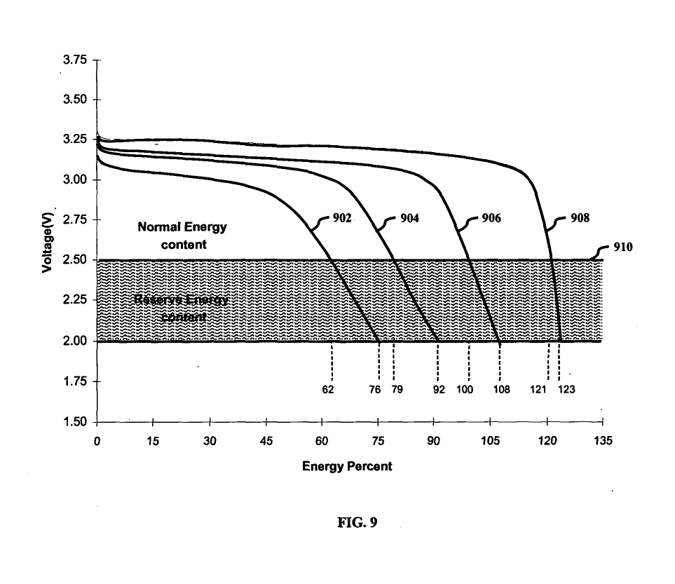

As mentioned earlier, the computed amount of internal reserve energy that exists at a point is refined based on current state of the ESS 102. In an embodiment, the current state of the ESS 102 is determined by the current temperature of the ESS. FIG. 9 is a graph illustrating the energy available in the ESS 102, in accordance with an embodiment. In the graph, lines 902, 904, 906 and 908 represent the availability of energy in the ESS 102 above the threshold level 910 and below the threshold level 910, at temperatures 0° C., 10° C., 25° C., and 40° C., respectively. It can be seen in the graph that the internal reserve energy is decreasing with the increase in temperature. The computation of internal reserve energy is refined by factoring in stored capacity as a function of rise in temperature. It may be noted that, based on the type of ESS, the refinement of the computed amount of internal reserve energy is carried out, as different types of ESS 102 may behave differently under different circumstances including those discussed above.

### Example Illustrating Calculation of Amount of Internal Reserve Energy

The example below provides calculation of amount of internal reserve energy in ESS 102, in accordance with an embodiment. In the example provided, the ESS 102 comprises Lithium Iron Phosphate Batteries. The amount of internal reserve energy in ESS 102 is calculated using data collected and plotted for the ESS 102 comprising Lithium Iron Phosphate Batteries as indicated in FIG. 6, FIG. 7, FIG. 8, FIG. 8b and FIG. 9.

Initially, capacity of the ESS 102 to store internal reserve energy is determined. In an embodiment, the amount of internal reserve energy depends on the threshold level that is configured and the intended capacity to store energy of the ESS 102. In this example the amount of internal reserve energy is determined as 150 AH; 6 kWH.

Further, the SOH of the ESS 102 is determined using historical data. In this Example, the ESS 102 has completed 500 charge/discharge cycles. The SOH of the ESS 102 is calculated as follows:

In FIG. 7, it is seen that the current capacity of the ESS 102 should be 90% of the original capacity. This particular observation is used to determine SOH by multiplying 0.9 with other factors that are considered to determine SOH. Further, in FIG. 5 it is observed that the actual measured capacity of the ESS 102 is actually 5% lower than the expected capacity. Hence a factor of 0.95 is multiplied with other factors that are used to determine SOH.

Further, impedance increase factor is used to determine SOH. FIG. 8b indicates abnormal increase in the impedance when compared with expected change in impedance. The impedance is 1.5 as against an expected value of 1. Further, as can be observed in FIG. 8, the effect of this impedance is to reduce the energy available by 10%. Hence, a factor of 0.9 is multiplied with other factors that are used for determining SOH.

In this embodiment, SOH=0.9*0.95*0.9

The SOH is used to refine the determined amount of internal reserve energy.

Internal reserve energy=150 AH*SOH or 6 kWH*SOH

Internal reserve energy=150*(0.9*0.95*0.9)=115.425 AH or 6*(0.9*0.95*0.9)=4.617 kWH.

It may be noted that in an embodiment, the SOH calculation can use additional parameters and calculations.

The amount of internal reserve energy that is refined using the SOH is further refined using the current state of the ESS 102. In this example, actual value of the temperature of the ESS 102 and energy variation as indicated in FIG. 9 is used to refine the refined amount of internal reserve energy. In this example, the ESS 102 is considered to be at 10 deg C. In FIG. 9, the capacity of the ESS 102 at this temperature is only 81% of expected. This correction is applied to the above value to arrive at an improved calculation of the amount of reserve energy.

Amount of reserve energy=115.425 AH×0.81=93.494 AH

Or

Amount of reserve energy=4.617 kWH×0.81=3.739 kWH

Determining Among of Work that can be Done Using the Internal Reserve Energy

In an embodiment, in addition to determining the amount of internal reserve energy available in the ESS 102, amount of work that can be done using the internal reserve energy available in the ESS 102 is determined.

In an embodiment, the amount of work that can be done is a measure of the distance a vehicle can travel, wherein the ESS 102 at least partially propels the vehicle. In another embodiment, the amount of work done is a measure of time the available internal reserve energy would last when energy is being consumed by one or more ECS 104.

In an embodiment, where the ESS 102 at least partially propels a vehicle, the distance that can be travelled by the vehicle is determined based on historic usage pattern.

In an embodiment, the historic usage pattern is derived from at least one of historic driving pattern and historic terrain pattern. Data representing the driving pattern is collected over a period of time to derive the historic driving pattern. The historic driving pattern indicates amount of energy utilized by the driver of the vehicle to cover a unit distance. For example, a driver who generally drives relatively fast, thereby consuming more energy would be able to cover less distance by using the internal reserve energy as compared to a driver who generally drives relatively at an ideal speed. Further, to derive the historic terrain pattern, data representing the driving terrain can be collected over a period of time to derive the historic terrain pattern. A vehicle which is being driven on relatively flat roads would be able to cover more distance by using the internal reserve energy as compared to a vehicle which is generally driven on steep roads (uphill roads). Further, the historic terrain pattern could also indicate whether the vehicle is generally driven in crowded roads with number of traffic signals, requiring more energy per unit distance driven, or whether the vehicle is generally driven in roads with free flowing traffic, thereby requiring less energy per unit distance driven.

In an embodiment, the energy stored in the ESS 102 is electrical energy.

In an embodiment, the energy stored in the ESS 102 is chemical energy.

In an embodiment, the amount of work that can be done using the internal reserve energy available in the ESS 102 is determined by the EMS 106.

In another embodiment, the amount of work that can be done using the internal reserve energy available in the ESS 102 is determined by the DPS 310.

In an embodiment, the amount of work that can be done using the internal reserve energy available is determined by considering the terrain in which a vehicle propelled at least partially by ESS 102 is driven. Information relating to the terrain can either be collected by the EMS 106 or DPS 310. In an embodiment, the information relating to the terrain is collected by using Global Positioning System (GPS). In an embodiment, at least one of EMS 106 and DPS 310 retrieves information relating to the terrain and climate conditions in which the vehicle is driven to determine the amount of work that can be done using the internal reserve energy.

In an embodiment, the amount of work that can be done using the internal reserve energy available is determined based on current driving pattern. The current driving pattern may be the energy consumed to cover a unit distance in the last few minutes of drive. The minutes of drive that is considered to determine the current driving pattern may be varied.

In an embodiment, the amount of work that can be done using the internal reserve energy available is determined based on ambient weather conditions. Ambient weather conditions such as one or more of weather, wind and rain, among others, which affects the amount of work that can be done using the internal reserve energy is considered to determine the amount of work that can be done using the internal reserve energy.

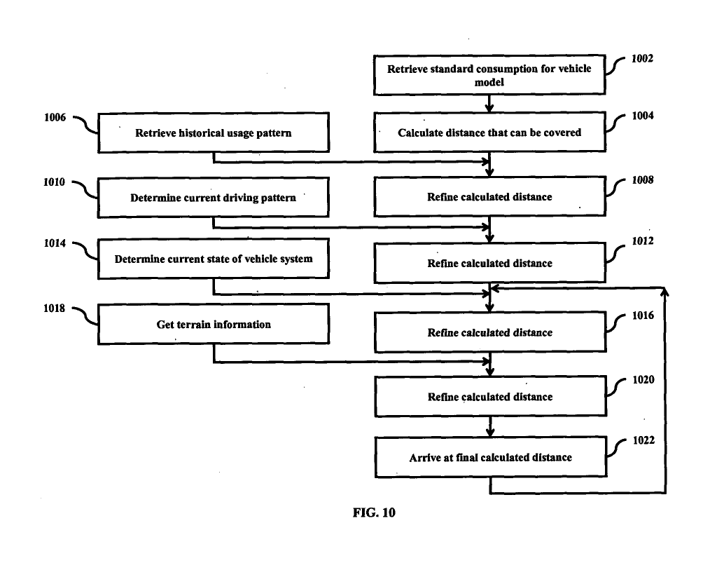

FIG. 10 is a flow chart illustrating a method of determining distance that can be covered (amount of work that can be done) using the internal reserve energy, in accordance with an embodiment. The amount of internal reserve energy that is determined is used to compute the distance that can be covered by the vehicle by using the internal reserve energy. This can be computed by retrieving standard consumption of energy for vehicle model at step 1002. Using the above information, the distance that can be covered is calculated at step 1004. In an embodiment the distance is calculated using the below formula:

Distance=internal reserve energy in watthours/standard consumption in watthour/kilometre.

Subsequent to determination of the distance, historic usage pattern is retrieved at step 1006. The usage pattern is used to refine the calculated distance by increasing or decreasing the calculated distance at step 1008. Additionally, current driving pattern is determined at step 1010, which is thereafter used to refine the calculated distance at step 1012. Further, state of one or more systems on the vehicle, such as temperature of one or more energy consumption systems such as motor, HVAC among others are determined at step 1014. The current state of the vehicle system is used to refine the calculated distance at step 1016. Additionally, information relating to terrain in which the vehicle is being driven is obtained at step 1018. In an embodiment, the terrain information is obtained by global positioning system. The terrain information is used to further refine the calculated distance and arrive at the final calculated distance at step 1022, which may be indicated to the user of the vehicle. In an embodiment, the refinement of the calculated distance is continuously performed as the vehicle is being driven.

The various actions in the above method may be performed in the order presented, in a different order or simultaneously. Further, in some embodiments, some actions listed in may be omitted.

In an embodiment, at least one of EMS 106 and DPS 310 determines locations of public ESS 102 charging points. Further, based on the calculated amount of work that can be done using the available internal reserve energy, it is determined whether a vehicle which is at least partially propelled by the ESS 102 can be driven to the nearest charging point. Further, based on the determination, adjustments are made to one or more profiles of energy consumption from the ESS 102 by ECS 104, so that the vehicle can at least be driven to the nearest charging point.

In an embodiment, the adjustments made to one or more profiles of energy consumption from the ESS 102 by ECS 104 include, restricting consumption of energy by HVAC from ESS 102 if the climate conditions permit such restriction.

In an embodiment, the adjustments made to one or more profiles of energy consumption from the ESS 102 by ECS 104 include, limiting consumption of energy by drive motor from ESS 102 so that the vehicle is driven relatively economically.

### Using Internal Reserve Energy

In an embodiment, the usage of the internal reserve energy available in the ESS 102 is triggered by a request to use the internal reserve energy.

In an embodiment, the request is automatically generated by the EMS 106 when the energy in the ESS 102 approaches the threshold level.

In another embodiment, the request is automatically generated by the EMS 106 when the energy in the ESS 102 reaches threshold level.

In another embodiment, the request is generated when a user actuates a button provided in a vehicle which is at least partially propelled by the ESS 102.

In another embodiment, a user of a vehicle which is at least partially propelled by the ESS 102 sends a request using his telecommunication device. In an embodiment, the request is sent via Short Messaging Service. In another embodiment, the request is made by calling a service centre which is capable of enabling usage of the internal reserve energy.

In an embodiment, the request is received by the DPS 310.

In an embodiment, after receiving the request, the usage of the internal reserve energy is either allowed or rejected based on the number of time the internal reserve energy has been utilized.

In an embodiment, after receiving the request, the usage of the internal reserve energy is either allowed or rejected based on whether the user of the ESS 102 has been entitled to allow the ESS 102 owned by the user to utilize the internal reserve energy in the ESS 102.

In an embodiment, the EMS 106 decides whether to allow or disallow the utilization of the internal reserve energy in the ESS 102.

In another embodiment, the DPS 310 decides whether to allow or disallow the utilization of the internal reserve energy in the ESS 102. The decision of the DPS 310 is communicated to the EMS 106, which enable the decision of the DPS 310.

In an embodiment, the decision whether to allow or disallow the utilization of the internal reserve energy in the ESS 102 is communicated to the user of the ESS 102.

In an embodiment, the decision whether to allow or disallow is communicated to the user of the ESS 102 via a display device associated with the ESS 102. In an embodiment, the display device is in a vehicle dashboard, wherein the ESS 102 at least partially propels the vehicle.

In an embodiment, the decision whether to allow or disallow is communicated to the user of the ESS 102 via a telecommunication device associated with the user.

The embodiment disclosed herein describes a method and system for determining amount of internal reserve energy that is available in an energy storage system. Therefore, it is understood that the scope of the protection is extended to such a program and in addition to a computer readable means having a message therein, such computer readable storage means contain program code means for implementation of one or more steps of the method, when the program runs on a server or mobile device or any suitable programmable device. The method may be implemented through or together with a software program written in e.g. Very high speed integrated circuit Hardware Description Language (VHDL) another programming language, or implemented by one or more VHDL or several software modules being executed on at least one hardware device. The hardware device can be any kind of portable device that can be programmed. The device may also include means which could be e.g. hardware means like e.g. an ASIC, or a combination of hardware and software means, e.g. an ASIC and an FPGA, or at least one microprocessor and at least one memory with software modules located therein. The method embodiments described herein could be implemented partly in hardware and partly in software. Alternatively, the invention may be implemented on different hardware devices, e.g. using a plurality of CPUs.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

1. A method of determining an amount of internal reserve energy that is available in an energy storage system, the method comprising:
determining capacity of the energy storage system to store energy;
collecting historical data relating to the energy storage system;
determining a state of health of the energy storage system based on the collected historical data;
determining a current state of the energy storage system;
computing an amount of internal reserve energy available below a threshold level based on the determined capacity; and
refining the computation of the amount of internal reserve energy that is available in the energy storage system based on the state of health of the energy storage system and current state of energy storage system.

2. The method according to claim 1, wherein collecting the historical data comprises collecting at least one of a capacity of the energy storage system to store energy, an age of the energy storage system, a recharging behavior of the energy storage system, a number of charge and discharge cycles the energy storage system has experienced, and an impedance of the energy storage system.

3. The method according to claim 2, wherein refining the computation of amount of internal reserve energy comprises reducing the computed amount of internal reserve energy with a reduction in the capacity of the energy storage system to store energy.

4. The method according to claim 2, wherein refining the computation of amount of internal reserve energy comprises reducing the computed amount of internal reserve energy with an increase in the age of the energy storage system.

5. The method according to claim 2, wherein collecting data relating to recharging behaviour of the energy storage system, comprises collecting data representing an increase in temperature of the energy storage system while charging the energy storage system.

6. The method according to claim 5, wherein refining the computation of amount of internal reserve energy comprises reducing the computed amount of internal reserve energy with an increase in the temperature of the energy storage system beyond an expected level while charging the energy storage system.

7. The method according to claim 2, wherein collecting data relating to recharging behaviour of the energy storage system, comprises collecting data representing a time taken to completely charge the energy storage system.

8. The method according to claim 7, wherein refining the computation of amount of internal reserve energy comprises reducing the computed amount of internal reserve energy with an increase in the time taken to completely charge the energy storage system.

9. The method according to claim 2, refining the computation of amount of internal reserve energy comprises reducing the computed amount of internal reserve energy with an increase in the number of charge and discharge cycles the energy storage system has experienced.

10. The method according to claim 2, wherein refining the computation of amount of internal reserve energy comprises reducing the computed amount of internal reserve energy with an increase in the impedance of the energy storage system.

11. The method according to claim 1, wherein refining the computation of amount of internal reserve energy comprises reducing the computed amount of internal reserve energy as the state of health of the energy storage system deteriorates.

12. The method according to claim 1, wherein determining the current state comprises collecting data representing the temperature of the energy storage system.

13. The method according to claim 12, wherein refining the computation of amount of internal reserve energy comprises increasing or decreasing the computed amount of internal reserve energy based on the temperature of the energy storage system.

14. The method according to claim 1, wherein the historical data is collected over a period of time.

15. The method according to claim 1, further comprising determining amount of work that can be done using the available internal reserve energy.

16. The method according to claim 15, wherein the amount of work that can be done is determined based on historic usage pattern.

17. The method according to claim 16, wherein the historic usage pattern is derived by collecting data representing at least one of historic driving pattern and historic terrain pattern.

18. The method according to claim 15, wherein the amount of work that can be done is determined based on energy consumed by one or more energy consumption system.

19. The method according to claim 15, wherein the amount of work that can be done is determined based on current driving pattern.

20. The method according to claim 15, wherein the amount of work that can be done is determined based on ambient weather conditions.

21. The method according to claim 15, wherein the amount of work that can be done is determined based on terrain in which a vehicle propelled by at least the energy storage system is driven.

22. The method according to claim 21, wherein the terrain in which the vehicle is driven is determined using a Global Positioning System.

23. The method according to claim 1, further comprising allowing usage of the available internal reserve energy in the energy storage system.

24. The method according to claim 23, wherein the usage of the internal reserve energy is allowed based on a request to use the internal reserve energy.

25. The method according to claim 24, wherein the request is sent by a user of the energy storage system.

26. The method according to claim 25, wherein the request is sent by the user by actuating a button provided in a vehicle in which the energy storage system is mounted.

27. The method according to claim 26, wherein the request is sent by the user by using a telecommunication device.

28. The method according to claim 24, wherein the request is sent automatically when the energy stored in the energy storage system approaches a threshold level or reaches a threshold level.

29. The method according to claim 23, wherein the usage of the available internal reserve energy in the energy storage system is allowed based on the number of times the internal reserve energy has already been used.

30. The method according to claim 23, wherein the usage of the available internal reserve energy in the energy storage system is allowed based on an eligibility of said energy storage system to use the available internal reserve energy.

31. The method according to claim 23, further comprising determining locations at which the energy storage system can be charged.

32. The method according to claim 31, further comprising adjusting a profile of energy consumption from the energy storage system by an energy consumption system, to enable a vehicle propelled at least partially by the energy storage system to at least reach the location which is nearest to the vehicle.

33. A system for determining internal reserve energy that is available in a energy storage system, the system being coupled to the energy storage system, the system comprising:
at least one energy management system comprising:
at least one input and output device configured to at least collect data from the energy storage system and send commands to the energy storage system;
at least one memory device configured to store at least a part of the data collected by the input and output device;
at least one processor configured to process at least a part of the data collected from the energy storage system; and
at least one transmitting and receiving device configured to send at least a part of the processed data and receive data;
a data processing system configured to receive data sent by the transmitting and receiving device and determine state of health of the energy storage and current state of the energy storage system, wherein the data processing system is configured to compute the amount of internal reserve energy available based on the state of health of the energy storage system.

34. The system according to claim 33, wherein the transmitting and receiving device is configured to communicate with the data processing system.

35. The system according to claim 33, wherein the processor is further configured to send commands to allow usage of the internal reserve energy from the energy storage system.

36. A system for determining internal reserve energy that is available in a energy storage system, the system coupled to the energy storage system, the system comprising at least one energy management system comprising:
at least one input and output device configured to at least collect data from the energy storage system and send commands to the energy storage system;
at least one memory device configured to store at least a part of the data collected by the input and output device; and
at least one processor configured to process at least a part of the data collected from the energy storage system and determine state of health of the energy storage system and current state of the energy storage system, wherein the processor is configured to compute the amount of internal reserve energy available based on the state of health of the energy storage system and current state energy storage system.

37. The system according to claim 36, wherein the processor is further configured to send commands to allow usage of the internal reserve energy from the energy storage system.

38. (canceled)

39. (canceled)
